(19) United States
(12) Patent Application Publication
(10) Pub. No.: US 2005/0179120 A1
(43) Pub. Date: Aug. 18, 2005

(54) Process for producing semiconductor device, semiconductor device, circuit board and electronic equipment

(76) Inventor: Koji Yamaguchi, Okinawa-shi (JP)

Correspondence Address: HARNESS, DICKEY & PIERCE, P.L.C., P.O. BOX 828, BLOOMFIELD HILLS, MI, 48303, US

(21) Appl. No.: 11/010,246

(22) Filed: Dec. 10, 2004

(30) Foreign Application Priority Data
Dec. 16, 2003 (JP) 2003-417954

(51) Int. Cl. H01L 23/495

(52) U.S. Cl. 257/666

(57) ABSTRACT

A process for producing a semiconductor device having a connection pin running through from the active surface of a substrate on which an electronic circuit is formed to the bottom side of the substrate, and an electrically conductive pattern electrically connected to the connection pin on the active side; the process including the steps of: forming a hole for embedding the connection pin in the active side, forming electrically conductive films serving as the connection pin and electrically conductive pattern in batch at the hole and the location on the active side communicating with the hole, polishing the surfaces of the electrically conductive films to be flat, and thinning the substrate to bare a portion of the connection pin at the bottom side of the substrate.

### BACKGROUND OF THE INVENTION

1. Field of the Invention

The present invention relates to a process for producing a semiconductor device, semiconductor device, a circuit board and an electronic equipment.

2. Description of the Related Art

Equipment such as portable electronic equipment including cell phones, notebook personal computers, personal digital assistants (PDA) as well as other equipment such as sensors, micromachines and printer heads are being required to employ smaller semiconductor chips and other electronic components provided therein in order to realize smaller size and lighter weight. In addition, the mounting space for these electronic components is extremely limited.

Consequently, research and development has been actively conducted in recent years on the production of ultra-compact semiconductor chips using wafer level chip scale package (W-CSP) technology. In W-CSP technology, since wafers are separated into individual semiconductor chips after carrying out reconfigured wiring (rewiring) and resin sealing in block while in the wafer state, semiconductor devices can be produced that have substantially the same surface area as the chip surface area.

In addition, three-dimensional mounting technology has also been proposed for further increasing the level of integration by attempting to increase the level of integration of semiconductor chips by laminating semiconductor chips having the same function or different functions and electrically connecting between each semiconductor chip. Furthermore, refer to the following patent documents 1 and 2 for further details on three-dimensional mounting technology of the prior art.
Patent document 1: Japanese Unexamined Patent Application, First Publication No. 2000-91496
Patent document 2: Japanese Unexamined Patent Application, First Publication No. 2000-277689

However, in the three-dimensional mounting technology of the prior art, connection pins that pass through a chip in the direction of thickness are provided on each chip in order to achieve continuity between laminated chips. In addition, in the case of achieving continuity for chips having different pin configurations, reconfigured wiring is formed on the chip surface, and continuity is achieved between this reconfigured wiring and the connection pin of the chip laminated on top.

However, the step for forming the connection pins is itself complex, and if a step for forming reconfigured wiring is added to this, considerable energy and time are required for chip production.

In consideration of these circumstances, the present invention was made, that is the object of the present invention is to provide a process for producing a semiconductor device that facilitates the production of high-performance, a three-dimensionally mounted semiconductor device, the resulting semiconductor device, and a circuit board and electronic equipment provided with this semiconductor device.

### SUMMARY OF THE INVENTION

In order to solve the aforementioned problems, a process for producing a semiconductor device of the present invention is a process for producing a semiconductor device having a connection pin that running through from the active surface of a substrate on which an electronic circuit is formed to the bottom side of the substrate, and an electrically conductive pattern electrically connected to the connection pin on the active side; the process comprising the steps of forming a hole for embedding the connection pin in the active side of the substrate, forming electrically conductive films serving as the connection pin and electrically conductive pattern in batch at the hole and the location on the active side that communicates with the hole, polishing the surfaces of the electrically conductive films to be flat, and thinning the substrate to bare a portion of the connection pin at the bottom side of the substrate, for example, etching the bottom side of the substrate to bare a portion of the connection pin and polishing the bottom side of the connection pin.

In the present invention, a through electrode in the form of a connection pin and a reconfigured wiring electrically connected thereto are formed in batch by plating and the like. Consequently, this process enables the production process to be simplified.

In addition, in the present process, since electrically conductive films serving as the connection pin and electrically conductive pattern are formed followed by imparting a uniform film thickness by polishing the electrically conductive films, a semiconductor device having desired electrical characteristics can be produced with stability. In other words, if hole embedding and electrically conductive pattern formation are performed by the same deposition step, the pattern thickness ends up changing according to the hole depth and hole diameter, thereby preventing the obtaining of uniform electrical characteristics. In the case of three-dimensional mounting technology in particular, since the hole diameter and other dimensions are different by more than a factor of ten as compared with ordinary semiconductor mounting technology, fluctuations in electrical characteristics become correspondingly larger. In addition, in the case of plating an electrically conductive film on the inside of a hole having a hole diameter on the order of several tens of micrometers, since the electrically conductive pattern is also correspondingly formed to a film thickness of several tens of micrometers, when a plurality of chips (semiconductor devices) having electrically conductive patterns of this film thickness are laminated, the intervals between the chips decrease making it difficult to fill sealing resin between the chips. In contrast, in the present process, there is no occurrence of fluctuations in electrical characteristics since the film thickness of the electrically conductive pattern can be controlled by polishing.

In addition, by adequately reducing the film thickness of the electrically conductive pattern over a range that does not impair electrical conductivity, the intervals between chips is increased, thereby facilitating the injection of sealing resin.

Furthermore, in the present process, the electrically conductive pattern is not limited to reconfigured wiring, but rather it may also be a pattern having a predetermined function in the manner of an inductor. In the present process, this type of functional pattern can be formed with a connection pin in batch. In addition, various methods such as wet etching, chemical mechanical polishing (CMP) or mechanical polishing can be performed in the aforementioned electrically conductive film polishing step.

In addition, an additional step may be provided in the present process in which a land is formed on the distal section of the reconfigured wiring. At this time, the outer diameter of the land is preferably formed to be greater than the wire width of the reconfigured wiring on which the land is arranged. As a result, connections between chips can be formed easily during three-dimensional mounting of a plurality of semiconductor devices (chips).

In addition, a process for producing a semiconductor device of the present invention includes a step of laminating a plurality of semiconductor devices produced by the aforementioned process, using a connection pin interposed therebetween.

As a result, three-dimensionally mounted semiconductor devices having desired electrical characteristics can be produced with stability.

In addition, a semiconductor device of the present invention is produced according to the aforementioned process. In addition, a circuit board or electronic equipment of the present invention are provided with the aforementioned semiconductor device. As a result, devices can be produced that have stable electrical characteristics.

### BRIEF DESCRIPTION OF THE DRAWINGS

FIGS. 1A-1D are process drawings for explaining a process for producing a semiconductor device of the present invention.

FIGS. 2A-2D are process drawings continuing from FIGS. 1A-1D.

FIG. 3A-3E are process drawings continuing from FIGS. 2A-2D.

FIG. 4 is a cross-sectional view showing the three-dimensional mounting state of a semiconductor device produced by the process of the present invention.

FIGS. 5A-5C are process drawing for explaining a connection pin formation step in a process for producing a semiconductor device of the present invention.

FIGS. 6A and 6B are process drawing continuing from FIGS. 5A-5C.

FIGS. 7A and 7B are process drawing continuing from FIGS. 6A and 6B.

FIGS. 8A and 8B are process drawing continuing from FIGS. 7A and 7B.

FIG. 9 is a schematic drawing showing the planar structure of a substrate on which reconfigured wiring has been formed.

FIG. 10 is a cross-sectional view showing an example of the general constitution of a three-dimensionally mounted semiconductor device.

FIG. 11 is a perspective view showing an example of a device equipped with a semiconductor device of the present invention.

FIG. 12 is a perspective view of an example of electronic equipment of the present invention.

### DETAILED DESCRIPTION OF THE INVENTION

Hereinafter, a process for producing a semiconductor device of the present invention will be explained, with reference to the drawings.

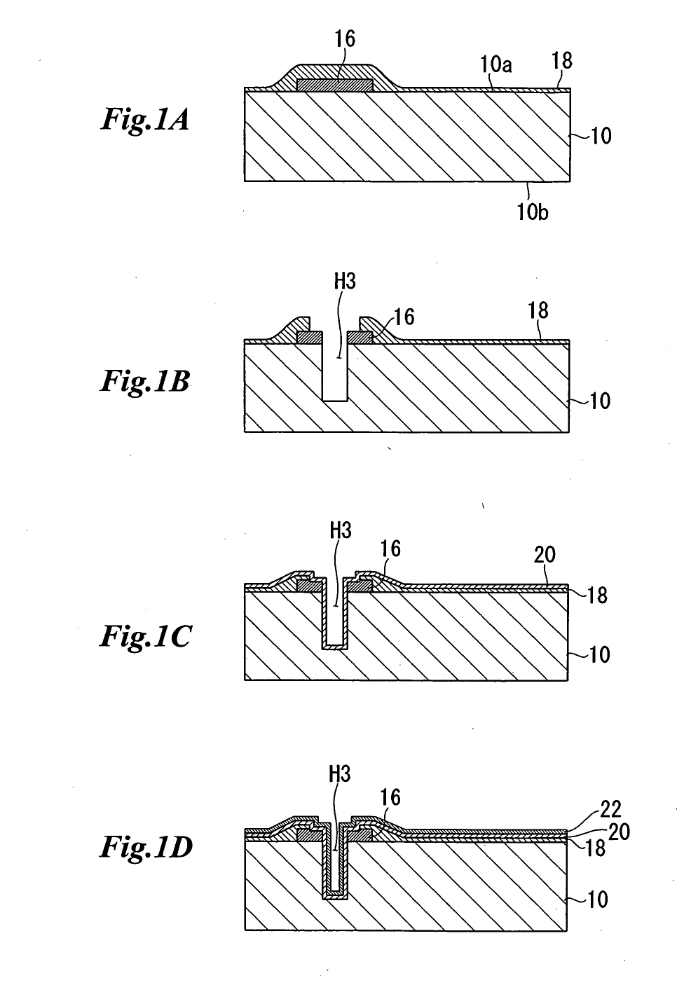

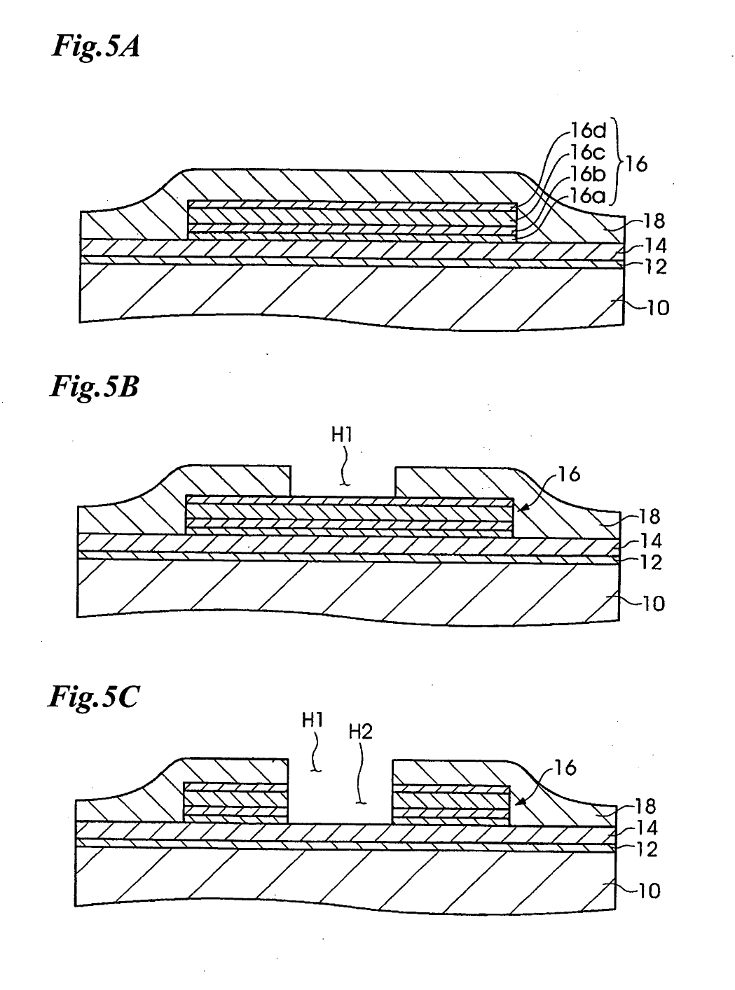

FIGS. 1A to 3E are process drawings for explaining the overall flow of the process of the present invention, while FIGS. 5A to 10 are process drawings that indicate in detail the method for forming its electrodes.

FIG. 1A is a schematic cross-sectional view showing a portion of a substrate to which the process of the present invention is applied. The processing target in the form of the substrate 10 is, for example, a silicon (Si) substrate, and electronic circuits composed of transistors, memory elements, other electronic elements, electrical wiring and the electrode pad 16 and the like are formed on the active side 10a thereof. On the other hand, these electronic circuits are not formed on the bottom side 10b of the substrate 10. The thickness of the substrate 10 is, for example, approximately 500 μm.

Here, the constitution of the active side 10a of the substrate 10 will be explained in detail.

FIG. 5A is a cross-sectional view showing in detail a portion of the constitution of the active side 10a of the substrate 10. As shown in FIG. 5A, the insulating film 12, composed of a silicon oxide (SiO₂) film made of silicon that is the base material of the substrate 10, and the interlayer insulating film 14 composed of boron-phosphorous-silicon glass (BPSG), are formed in that order on the substrate 10.

In addition, the electrode pad 16 electrically connected to the electronic circuits formed on the active side 10a of the substrate 10 is formed at a location not shown in the drawings on a portion of the interlayer insulating film 14. This electrode pad 16 is formed by sequentially laminating the first layer 16a composed of titanium (Ti), the second layer 16b composed of titanium nitride (TiN), the third layer 16c composed of aluminum/copper (AlCu) and the fourth layer (cap layer) 16d composed of TiN. Furthermore, it should be noted that electronic circuits are not formed below the electrode pad 16.

The electrode pad 16 forms a laminated structure composed of the first layer 16a through the fourth layer 16d over the entire the interlayer insulating film 14 by, for example, sputtering, and is formed by patterning to a predetermined shape (e.g., circular shape) using a resist and the like. Furthermore, although the case of the electrode pad 16 being formed by the aforementioned laminated structure is explained as an example in the present embodiment, the electrode pad 16 may also be formed with aluminum (Al) only. In addition, the electrode pad 16 is preferably formed made of copper because of its low electrical resistance. In addition, the electrode pad 16 is not limited to the aforementioned constitution, but rather the constitution may be suitably changed according to the required electrical characteristics, physical characteristics or chemical characteristics.

In addition, the passivation film 18 is formed on the aforementioned interlayer insulating film 14 so as to cover a portion of the electrode pad 16. This passivation film 18 is formed from silicon oxide (SiO₂), silicon nitride (SiN) or polyimide resin and the like, or employs a constitution in which SiO₂ is laminated on SiN, although the opposite is preferable. In addition, the film thickness of the passivation film 18 is preferably approximately 2 to 6 μm.

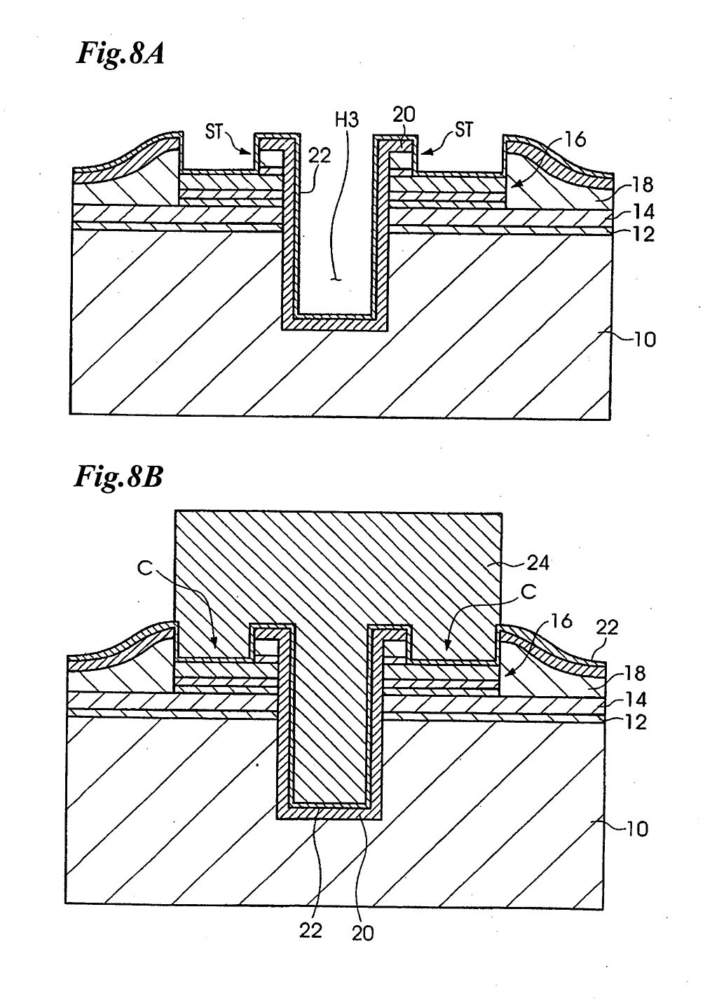

The film thickness of the passivation film 18 is preferably 2 μm or more because it is necessary in terms of securing the aforementioned selection ratio. In addition, the film thickness of the passivation film 18 is preferably 6 μm or less because it is necessary to etch the passivation film 18 on the electrode pad 16 when electrically connecting connection pins (see FIG. 8B) formed on the electrode pad 16 to the electrode pad 16 in a step to be described later, and if the thickness if too large, there is the risk of lowering the production process.

First, as shown in FIG. 1B, a step is performed on the substrate 10 having the aforementioned constitution in which the hole H3 is formed in the active side 10a of the substrate 10. FIG. 1B is a cross-sectional view showing the state in which the hole H3 is formed in the substrate 10. This hole H3 is forming a connector in the form of the connection pin 24 serving as an external pin of an electronic circuit formed on the active side 10a of the substrate 10 to a shape that allows a portion thereof to be embedded in the substrate 10. This hole H3 is formed so as to penetrate the electrode pad 16 at the location of the electrode pad 16 shown in FIG. 5A. Here, a detailed explanation is provided of the step in which the hole H3 is formed with reference to FIGS. 5 to 7.

First, a resist (not shown) is coated onto the entire surface of the passivation film 18 by a method such as spin coating, dipping or spray coating, etc. Furthermore, this resist is used for forming an opening in the passivation film 18 that covers the electrode pad 16, it may be of any type of resist such as a photoresist, electron beam resist or X-ray resist, and it may be in the form of a positive resist or negative resist.

When the resist has been coated onto the passivation film 18, exposure and development treatment are performed following pre-baking using a mask in which a predetermined pattern is formed to pattern the resist to a predetermined shape. Furthermore, the shape of the reset is set corresponding to the shape of the opening of the electrode pad 16 and the cross-sectional shape of the hole formed in the substrate 10. When patterning of the resist has been completed, post-baking is performed and a portion of the passivation film 18 that covers the electrode pad 16 is etched as shown in FIG. 5B to form the opening H1. FIG. 5B is a cross-sectional view showing the state in which the opening H1 has been formed by forming an opening in the passivation film 18.

Furthermore, dry etching is preferably applied for etching the passivation film 18. The dry etching may be reactive ion etching (RIE). In addition, wet etching may also be applied for etching the passivation film 18. The cross-sectional shape of the opening H1 formed in the passivation film 18 is set corresponding to the shape of the opening in the electrode pad 16 formed in a step to be described later and the cross-sectional shape of the hole formed in the substrate 10, and its diameter is set to be approximately the same as the diameter of the opening formed in the electrode pad 16 and the hole formed in the substrate 10, for example, approximately 50 μm.

When the aforementioned step has been completed, an opening is formed in the electrode pad 16 by dry etching using the resist on the passivation film 18 in which the opening H1 is formed as a mask. FIG. 5C is a cross-sectional view showing the state in which the opening H2 has been formed by forming an opening in the electrode pad 16. Furthermore, the resist is not shown in FIGS. 5A to 5C. As shown in FIG. 5C, the diameter of the opening H1 formed in the passivation film 18 and the diameter of the opening H2 formed in the electrode pad 16 are substantially the same. Furthermore, RIE can be used for dry etching.

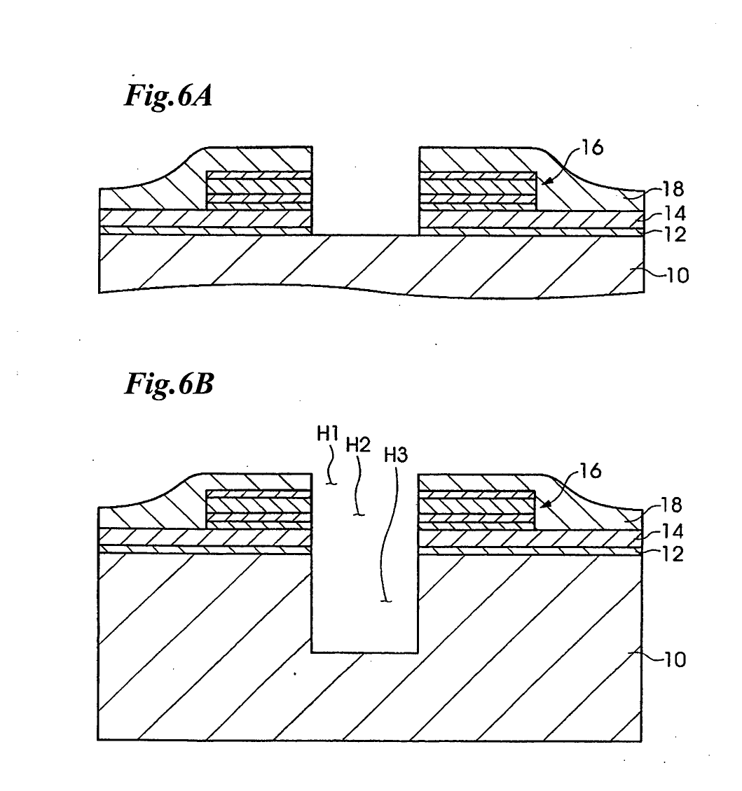

Moreover, the substrate 10 is bared as shown in FIG. 6A by next etching the interlayer insulating film 14 and the insulating film 12 using the resist used in the aforementioned steps as a mask. FIG. 6A is cross-sectional view showing the state in which a portion of the substrate 10 has been bared by etching the interlayer insulating film 14 and the insulating film 12. Subsequently, the resist formed on the passivation film 18 that has been used as an opening mask is removed using a liquid remover or by ashing.

Furthermore, although etching was repeated using the same resist mask in the aforementioned process, the resist may naturally be re-patterned following completion of each etching step. In addition, the substrate 10 can also be bared as shown in FIG. 6A by removing the resist after forming the opening H2 formed in the electrode pad 16, and etching the interlayer insulating film 14 and the insulating film 12 using uppermost TiN layer of the electrode pad 16 as a mask. In addition, it is necessary to increase the thickness of the resist in consideration of the selection ratio during each etching.

When the aforementioned step has been completed, a hole is bored in the substrate 10 as shown in FIG. 6B by dry etching using the passivation film 18 as a mask. Furthermore, in addition to RIE, inductively coupled plasma (ICP) can also be used for dry etching. FIG. 6B is a cross-sectional view showing the state in which the hole H3 has been formed by boring the substrate 10.

As shown in FIG. 6B, since the hole H3 is bored in the substrate 10 by using the passivation film 18 as a mask, the diameter of the hole H3 formed in the substrate 10 is substantially the same as the diameter of the opening H1 formed in the passivation film 18. As a result, the diameter of the opening H1 formed in the passivation film 18, the diameter of the opening H2 formed in the electrode pad 16, and the diameter of the hole H3 formed in the substrate 10 are all substantially the same. Furthermore, the depth of the hole H3 is suitably set corresponding to the thickness of the semiconductor chip ultimately formed.

In addition, as shown in FIG. 6B, it can be understood that when the hole H3 is formed in the substrate 10, a portion of the passivation film 18 is etched by dry etching and its film thickness decreases. Here, during formation of the hole H3, it is not preferable in terms of proceeding to subsequent steps or securing reliability as a semiconductor device if a state occurs in which the electrode pad 16 or the interlayer insulating film 14 is bared as a result of removing the passivation film 18 by etching. Consequently, the film thickness of the passivation film 18 is set to be 2 μm or more in the state shown in FIG. 5A.

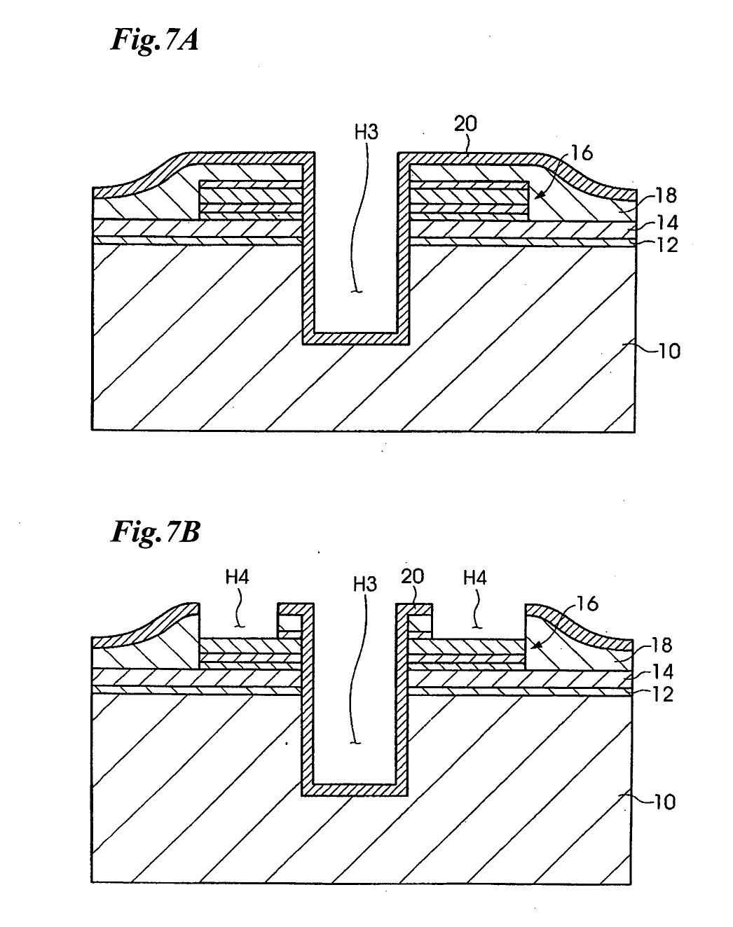

When the aforementioned step has been completed, the insulating film 20 is next formed over the electrode pad 16 and on the inner walls and bottom of the hole H3. FIG. 7A is a cross-sectional view showing the state in which the insulating film 20 has been formed over the electrode pad 16 and on the inner walls and bottom of the hole H3. This insulating film 20 is provided to prevent the generation of leakage current as well as corrosion and the like of the substrate 10 caused by oxygen, moisture and the like, and tetraethyl orthosilicate (Si(OC₂H₅)4, TEOS), formed using plasma enhanced chemical vapor deposition (PECVD), abbreviated as PE-TEOS, TEOS formed using ozone CVD, abbreviated as O₃-TEOS, or silicon oxide formed using CVD, can be used. Furthermore, the thickness of the insulating film 20 is, for example, 1 μm.

Continuing, a resist (not shown) is coated onto the entire surface of the passivation film 18 by a method such as spin coating, dipping or spray coating. Alternatively, a dry film resist may be used instead. Furthermore, this resist is used to form an opening in a portion of the electrode pad 16, it may of any type of resist such as a photoresist, electron beam resist or X-ray resist, and it may be in the form of a positive resist or negative resist.

When the resist has been coated onto the passivation film 18, exposure and development treatment are performed following pre-baking using a mask in which a predetermined pattern is formed to pattern the resist to a shape in which the resist only remains at those sections other than over the electrode pad 16, at the hole H3 and its periphery, such as a circular shape centered about the hole H3. When patterning of the resist has been completed, post-baking is performed followed by removing the insulating film 20 and the passivation film 18 that cover a portion of the electrode pad 16 to form an opening in a portion of the electrode 16. Furthermore, dry etching is preferably applied for etching. The dry etching may be reactive ion etching (RIE). In addition, wet etching may also be applied for the etching. Furthermore, the fourth layer 16d that composes the electrode pad 16 is also removed at this time.

FIG. 7B is a cross-sectional view showing the state in which a portion of the insulating film 20 and the passivation film 18 that cover the electrode pad 16 have been removed. As shown in FIG. 7B, the opening H4 is located over the electrode pad 16 causing a portion of the electrode 16b to be bared. Connection pin (electrode section) 24 formed in a later step and the electrode pad 16 are able to be connected by the opening H4. Thus, the opening H4 should be formed at a site other than the site where the hole H3 is formed. In addition, it may also be adjacent thereto.

The present embodiment describes the example of the case in which the hole H3 (the opening H1) is formed nearly in the center of the electrode pad 16. Accordingly, making the opening H4 so as to surround the hole H3, or in other words increasing the bared surface area of the electrode pad 16, is preferable in terms of reducing the connection resistance between the electrode pad 16 and a connection pin formed later. In addition, the location where the hole H3 is formed is not required to be nearly in the center of an electrode pad, and a plurality of holes may be formed. Furthermore, when a portion of the electrode pad 16 is bared by removing a portion of the insulating film 20 and the passivation film 18 that cover electrode 16, the resist used during removal is removed with a liquid remover.

The hole H3 shown in FIG. 1B and the insulating film 20 shown in FIG. 1C are formed by going through the steps described above. When the hole H3 and the insulating film 20 are formed on the substrate 10 in this manner, a step is performed in which the under layer film 22 is formed on the substrate 10 as shown in FIG. 1D. FIG. 8A is a cross-sectional view showing the state in which the under layer film 22 is formed in the hole H3. Here, since the under layer film 22 is formed on the entire upper surface of the substrate 10, the under layer film 22 is formed on both the inner walls and bottom of the hole H3 as well as the bared portion of the electrode pad 16. Here, the under layer film 22 is composed of a barrier layer and a seed layer, and is deposited by first forming the barrier layer followed by forming the seed layer on the barrier layer. The barrier layer is formed from, for example, TiW, while the seed layer is formed from Cu. These can be formed by using a method such as the ion metal plasma (IMP) method, vacuum deposition, sputtering, ion plating or other physical vapor deposition (PVD) method.

FIG. 8A is a cross-sectional view showing the state in which the under layer film 22 has been formed in the hole H3. As shown in FIG. 8A, the under layer film 22 is formed continuously over the electrode pad 16 and the insulating film 20 (including inside the hole H3) while adequately covering step ST between the electrode pad 16 and the insulating film 20. Furthermore, the film thickness of the barrier layer that composes the under layer film 22 is, for example, approximately 100 nm, while the film thickness of the seed layer is, for example, approximately several hundred nm. Since the under layer film 22, which is necessary for forming the connection pin 24 and reconfigured wiring 42 to be described later, on the substrate 10 in a single step in the present embodiment in this manner, the production process can be simplified.

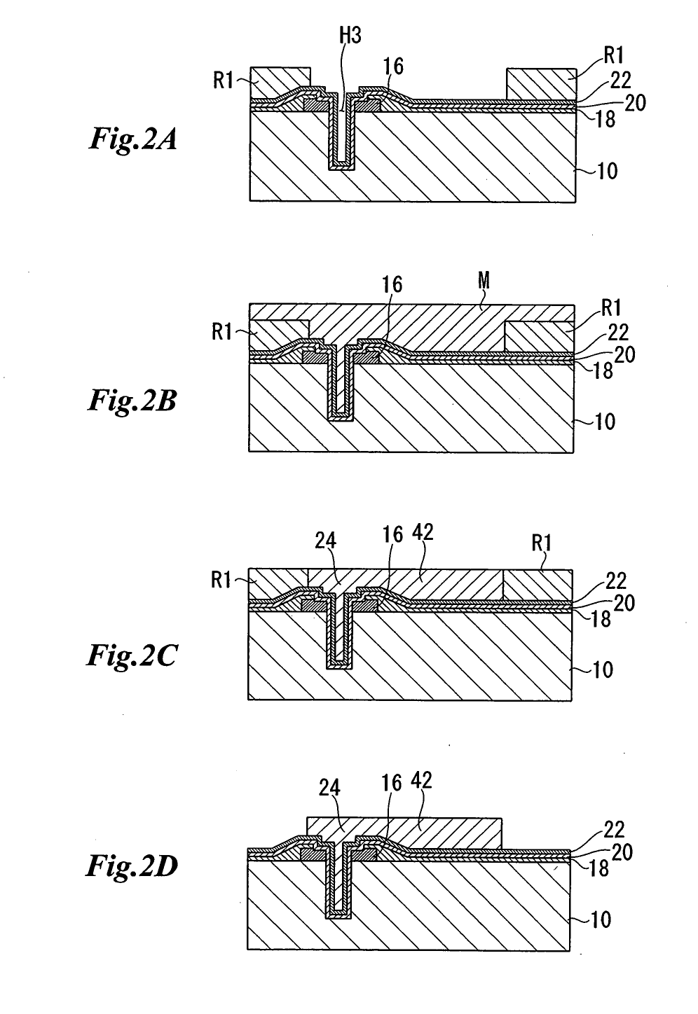

When formation of the under layer film 22 is completed, as shown in FIG. 2A, a plating resist is coated onto the active side 10a of the substrate 10, and plating the resist pattern R1 is formed by patterning in the state in which only the portions where the connection pin 24 and the reconfigured wiring 42 are formed are open. Subsequently, Cu electrolytic plating is performed and as shown in FIG. 2B, the electrically conductive film M made of copper (Cu) and the like is plated at the locations where the opening H3 of the substrate 10 and the reconfigured wiring 42 are formed. At this time, since the diameter of the hole H3 is becomes as much as several tens of micrometers, when the electrically conductive film M is attempted to be completely filled into the hole, the electrically conductive film M formed at the area of reconfigured wiring also becomes a correspondingly thick film. Consequently, in the case that it becomes difficult to adequately obtain flatness of the film surface and wiring is reconfigured while in this state, fluctuations occur in the electrical characteristics. In addition, since the thickness of the electrically conductive film M at the area of reconfigured wiring changes corresponding to the diameter of the hole H3, it becomes difficult to control the wiring thickness to a constant thickness. Moreover, if this type of thick film reconfigured wiring is formed on the active side, the interval between chips becomes smaller during lamination of chips, thereby also resulting in the possibility of it being difficult to inject sealing resin between the chips. Therefore, in the process of the present invention, after forming the electrically conductive film M on the substrate 10, the active side 10a is polished by a method such as wet etching, chemical mechanical polishing (CMP) or mechanical polishing to make the film thickness of the electrically conductive film M uniform (i.e., flat). FIG. 1C is a cross-sectional view showing the state after the polishing step has been performed. As a result of performing this step, the connection pin 24 and the reconfigured wiring 42 are formed in batch at the hole H3 and at the location on the active side that communicates therewith, respectively.

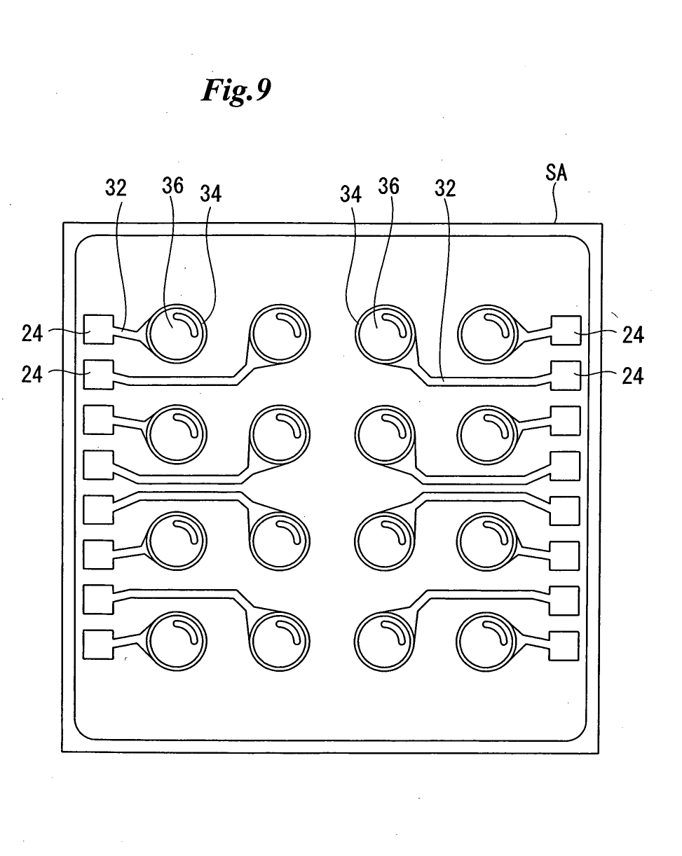

Furthermore, in the aforementioned step, the pad 34 (see FIG. 9) is preferably formed on the distal section of the reconfigured wiring 42 (namely, the outer diameter of the reconfigured wiring 42 is formed to be larger than the width of the wiring from the connection pin 24 to this distal section). As a result, it becomes easier to achieve electrical continuity between chips when a plurality of semiconductor devices (chips) are laminated.

When the connection pin 24 and the reconfigured wiring 42 are formed, as shown in FIG. 2D, plating the resist pattern R1 formed on the substrate 10 is removed. FIG. 2D is a cross-sectional view showing the state in which plating the resist pattern R1 has been removed. In addition, FIG. 8B is a cross-sectional view showing the details of the constitution of formed the connection pin 24. As shown in FIG. 2D, together with the connection pin 24 having the shape of a projection that protrudes from the active side 10a of the substrate 10, it also has a shape of which a portion is embedded in the substrate 10. In addition, as shown in FIG. 8B, the connection pin 24 is electrically connected to the electrode pad 16 at the location denoted by reference symbol C.

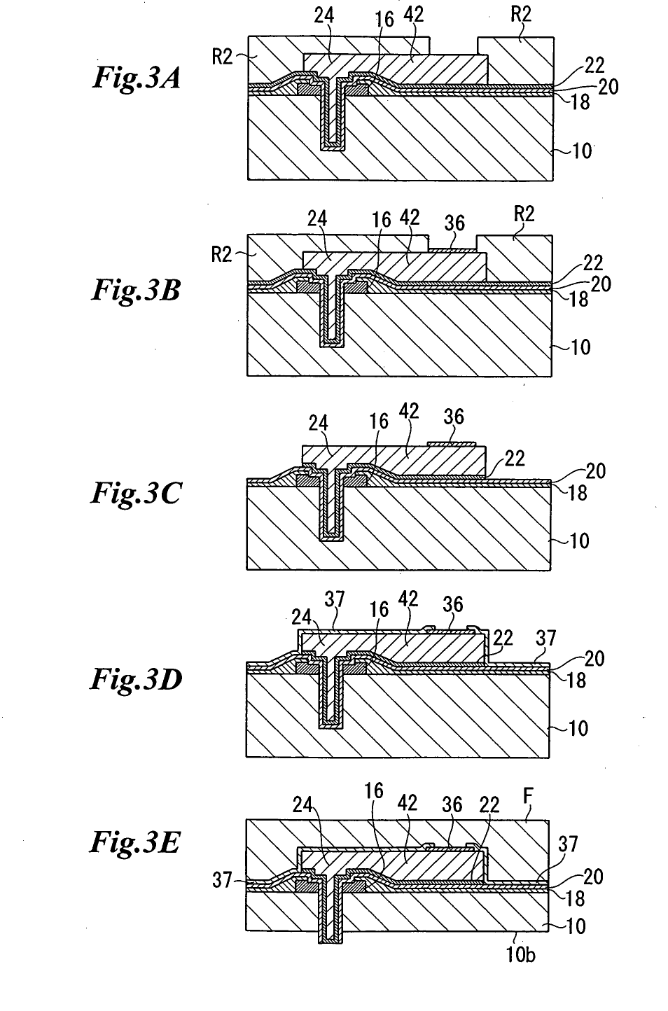

When formation of the reconfigured wiring 42 is completed, as shown in FIG. 3A, a resist is coated on the active side 10a of the substrate 10, and the resist pattern R2 is formed by patterning in the state in which an opening is formed only the distal section of the reconfigured wiring 42. Subsequently, the solder or other soldering material 36 is formed on the distal section (the pad 34) of the reconfigured wiring 42 using a method such as electrolytic plating. FIG. 3B is a cross-sectional view showing the state following formation of the soldering material. Furthermore, examples of materials that can be used for soldering the material 36 include tin/silver, lead-free solder, metal paste and molten paste. Furthermore, the solder referred to in the present specification includes lead-free solder.

When soldering the material 36 is formed, the resist pattern R2 formed on the substrate 10 is removed. Subsequently, a seed layer is etched by etching the entire active side 10 of the substrate 10, including the reconfigured wiring 42. Here, since the film thickness of the reconfigured wiring 42 is thicker than the film thickness of the seed layer, the reconfigured wiring 42 is not completely etched by etching.

Next, the unnecessary portion of the barrier layer is removed by RIE. At this time, since the reconfigured wiring 42 composed of copper (Cu) is not etched by RIE, the barrier layer other than the barrier layer directly below the reconfigured wiring 42 is etched as a result of the reconfigured wiring 42 serving as a mask. Furthermore, in the case of etching the barrier layer and seed layer by wet etching, it is necessary to use an etching liquid that is resistant to the copper (Cu) that forms the reconfigured wiring 42.

Here, the unnecessary section of the under layer film 22 refers to, for example, the portion other than where the connection pin 24 and the reconfigured wiring 42 are formed, namely the portion where the under layer film 22 is bared. Since etching of the under layer film 22, which is necessary for respectively forming the connection pin 24 and the reconfigured wiring 42, is performed in a single step in the present embodiment as described above, the production process can be simplified.

FIG. 3C is a cross-sectional view showing the state in which the unnecessary portion of the under layer film 22 has been etched following formation of the reconfigured wiring 42. In the example shown in FIG. 3C, the under layer film 22 can be seen to be etched to the reconfigured wiring 42. FIG. 9 is an overhead view of the substrate 10 on which the reconfigured wiring 42 and soldering material 36 have been formed. Furthermore, a plurality of zones (shot areas) are set on the active side 10a of the substrate 10, and although similar electronic circuits are frequently formed in each of these zones, only one of these zones SA is shown in FIG. 9.

As shown in FIG. 9, the connection pins 24 are formed and arranged along on pair of opposing sides of the shot area, and the reconfigured wiring 24 is formed in the state in which one end is connected to each the connection pin 24. In addition, a land is formed on the distal end of each the reconfigured wiring 42 that has an outer diameter that is larger than the wire width due to the soldering material 36.

When the aforementioned step has been completed, as shown in FIG. 3D, a solder resist is coated onto the active side 10a of the substrate 10, and the solder resist pattern 37 is formed by patterning in the state in which an opening is formed in a portion of the land 36. Subsequently, a step is performed in which the active side 10a of the substrate 10 is supported by the support material F, and thinning of the substrate 10 to bare a portion of the connection pin 24 to the bottom side of the substrate 10 is performed. Concretely, the bottom side 10b of the substrate 10 is etched to bare a portion of the connection pin 24, and the bottom side of the connection pin 24 is polished. FIG. 3E is a cross-sectional view showing the state following polishing of the bottom side of the substrate 10. When the bottom side of the substrate 10 is polished, the thickness of the substrate 10 is reduced by approximately 50 μm, causing a portion of the connection pin 24 to protrude from the bottom side of the substrate 10 by approximately 20 μm.

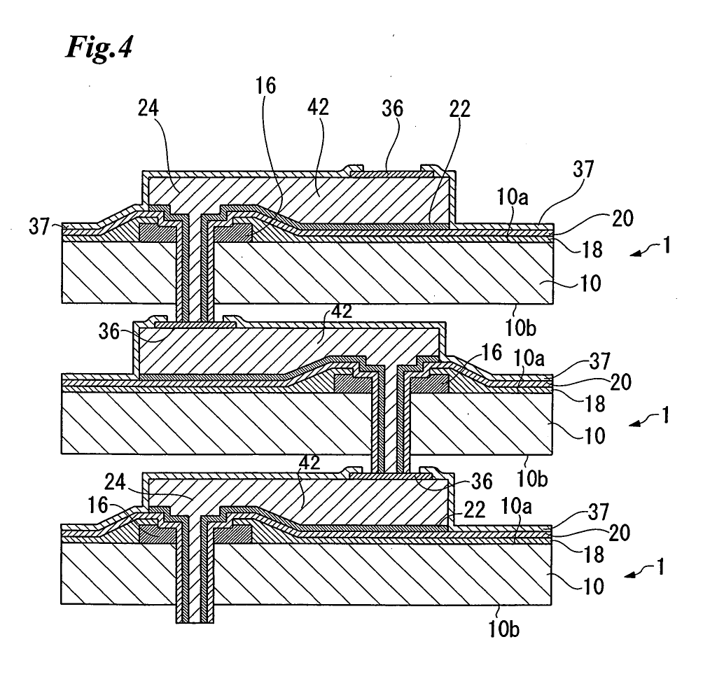

A semiconductor device that has been produced by going through the aforementioned steps is in the state in which the connection pin 24 is bared on both the top side and bottom side of the substrate 10. Consequently, as shown in FIG. 4, by using a plurality of the semiconductor devices 1 obtained according to the process of the present invention and laminating each the semiconductor device 1 by means of the connection pins 24, a three-dimensionally mounted (stacked) semiconductor device can be produced that allows high-density mounting.

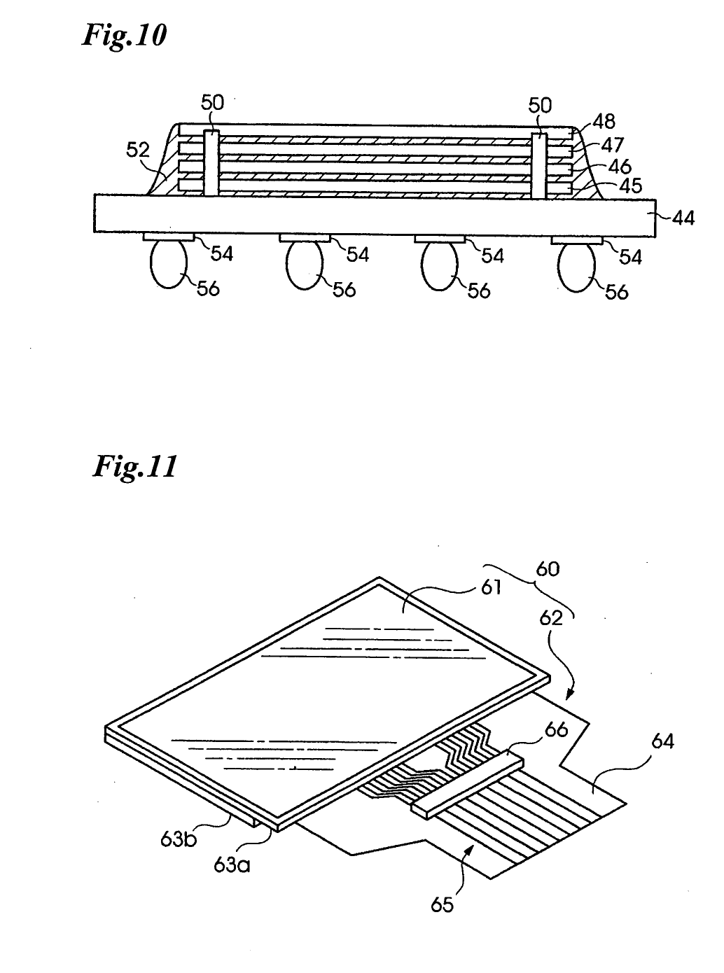

FIG. 10 is a cross-sectional view showing an example of the general constitution of a three-dimensionally mounted semiconductor device. In FIG. 10, the reference symbol 44 indicates a circuit board, while reference symbols 45 to 48 indicate semiconductor chips. The semiconductor chips 45 to 48 are laminated sequentially, and each is connected electrically by the electrodes 50. The connection pins 24 formed on each the semiconductor chip 45 to 48 are electrically connected to the electrodes 50. The laminated semiconductor chips 45 to 48 are installed on the circuit board 44.

The circuit board 44 is an organic substrate such as a glass epoxy board, and a wiring pattern composed of copper, for example, is formed to yield a desired circuit. The laminated semiconductor chips 45 to 48 are installed by positioning relative to the circuit board 44, and the wiring patterns formed on the circuit board 44 are electrically connected to the electrodes 50. In addition, the semiconductor chips 45 to 48 installed on the circuit board 44 are sealed with the sealing resin 52. The electrode pads 54 electrically connected to the wiring patterns formed on the circuit board 44 are formed on the bottom side of the circuit board 44. The solder balls 56 are formed on these electrode pads 54. A semiconductor chip having this type of constitution offers compact size, toughness, light weight and multiple functions.

As has been explained above, in the process for producing a semiconductor device of the present invention, since the connection pins 24, serving as external electrodes of an electronic circuit, and the reconfigured wiring 42, which are connected electrically thereto, are formed in batch by a plating method, the production process can be simplified. In addition, in the process of the present invention, since the electrically conductive films M serving as the reconfigured wiring 42 and the connection pins 24 are formed followed by polishing the active side 10a of the substrate 10 to make the film thickness of these electrically conductive films (i.e., the reconfigured wiring 42) uniform, semiconductor devices having desired electrical characteristics can be produced with stability.

Furthermore, although the present embodiment has been explained with respect to a method for forming connection pins 24 and the reconfigured wiring 42 in batch, it is not limited to this type of reconfigured wiring in the case of being able to form the connection pins 24 in batch. For example, a functional electrically conductive pattern such as an inductor can also be integrally formed with the connection pins 24 on the active side 10a. As a result, the process can be simplified as compared with the case of forming each in separate steps. Naturally in this case as well, the surface of electrically conductive films serving as connection pins and a functional pattern (such as an inductor) is polished to make the film thickness uniform after having formed the electrically conductive films as necessary.

[Electrooptical Device and Circuit Board]

FIG. 11 is a perspective view showing the appearance of a device as claimed in an embodiment of the present invention (e.g., electrooptical device). Furthermore, a liquid crystal display device is shown as an example of the electrooptical device shown in FIG. 11. This electrooptical device 60 is composed of the liquid crystal display panel 61 and the relay board 62.

The liquid crystal display panel 61 has a pair of the boards 63a and 63b adhered by a sealing material not shown. Liquid crystal is injected into the gap, or so-called cell gap, formed between the boards 63a and 63b. In other words, liquid crystal is sandwiched between the boards 63a and 63b.

The relay board 62 has a plurality of the wiring patterns 65 formed on the flexible resin board 64 made of polyimide and the like, and the semiconductor chip 66 is installed on a portion of the resin board 64.

Furthermore, a drive circuit that drives, for example, a thin film transistor (TFT) or other switching element formed on the liquid crystal display panel 61, is formed on the aforementioned semiconductor chip 66.

The semiconductor chip 66 is installed on the resin board 64 in the state in which it is electrically connected to the wiring pattern 65 formed on the resin board 64 using, for example, an anisotropic conductive film (ACF). This anisotropic conductive film is formed by, for example, dispersing a large number of electrically conductive particles in a thermoplastic or thermosetting adhesive resin. Furthermore, the liquid crystal panel 61 and the relay board 62 are also preferably connected by an anisotropic conductive film. Furthermore, the semiconductor chip 66 installed on the relay board 62 is a semiconductor device produced using the previously described process.

[Electronic Equipment]

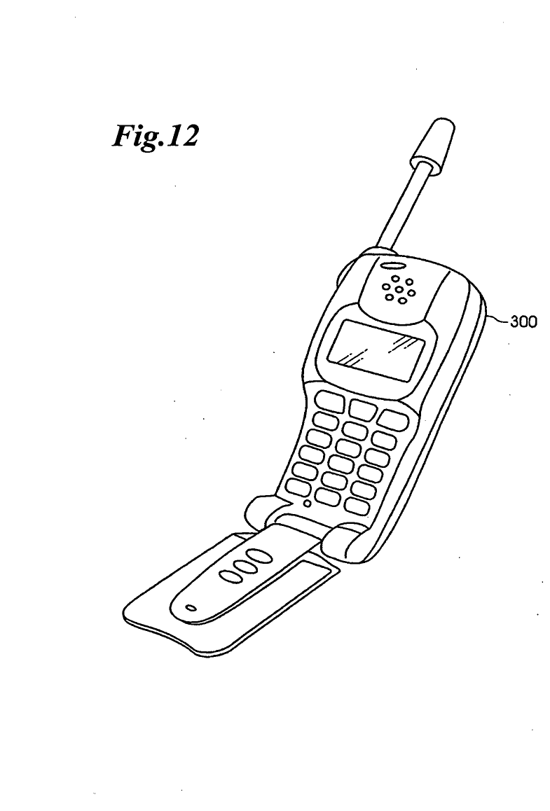

FIG. 12 is a perspective view showing the general constitution of a cell phone as an embodiment of electronic equipment of the present invention. As shown in FIG. 12, the cell phone 300 is equipped with the aforementioned semiconductor device or the aforementioned circuit board within its case.

Furthermore, an example of electronic equipment is not limited to the aforementioned cell phone, but rather the present invention can be applied to various other types of electronic equipment, examples of which include notebook computers, liquid crystal projectors, multimedia-compatible personal computers (PC), engineering workstations (EWS), pagers, word processors, television sets, viewfinder or direct-view monitor-type video tape recorders, electronic memo pads, electronic desktop calculators, car navigation systems, POS terminals and other electronic equipment such as devices equipped with a touch panel.

While preferred embodiments of the invention have been described and illustrated above with reference to the attached drawings, it should be understood that these are exemplary of the invention and are not to be considered as limiting. Additions, omissions, substitutions and other modifications can be made without departing from the spirit or scope of the present invention. Accordingly, the invention is not to be considered as being limited by the foregoing description, and is only limited by the scope of the appended claims.

1. A process for producing a semiconductor device having a connection pin running through from the active surface of a substrate on which an electronic circuit is formed to the bottom side of said substrate, and
an electrically conductive pattern electrically connected to the connection pin on the active side;
said process comprising the steps of:
forming a hole for embedding the connection pin in the active side,
forming electrically conductive films serving as the connection pin and electrically conductive pattern in batch at the hole and the location on the active side communicating with the hole,
polishing surface of the electrically conductive films to be flat, and
thinning the substrate to bare a portion of the connection pin at the bottom side of the substrate.

2. A process for producing a semiconductor device as set forth in claim 1, wherein the electrically conductive films are formed by plating.

3. A process for producing a semiconductor device as set forth in claim 1, wherein the electrically conductive pattern is reconfigured wiring.

4. A process for producing a semiconductor device as set forth in claim 3, further comprising the step of forming a land on the distal section of the reconfigured wiring.

5. A process for producing a semiconductor device as set forth in claim 4, wherein the outer diameter of the land is formed to be greater than the wire width of the reconfigured wiring on which the land is arranged.

6. A process for producing a semiconductor device as set forth in claim 1, wherein said polishing of the electrically conductive films is performed by wet etching.

7. A process for producing a semiconductor device as set forth in claim 1, wherein said polishing of the electrically conductive films is performed by chemical mechanical polishing.

8. A process for producing a semiconductor device as set forth in claim 1, wherein said polishing of the electrically conductive films is performed by mechanical polishing.

9. A process for producing a semiconductor device comprising the step of forming a plurality of semiconductor devices produced by the process as set forth in claim 1, and each semiconductor device is laminated with the connection pin interposed there between.

10. A semiconductor device produced by the process as set forth in claim 1.

11. A circuit board comprising said semiconductor device as set forth in claim 10.

12. An electronic equipment comprising said semiconductor device as set forth in claim 10.
